(19) United States
(12) Patent Application Publication
(10) Pub. No.: US 2025/0331142 A1
(43) Pub. Date: Oct. 23, 2025

(54) RECYCLING CIRCUIT BOARD COMPONENTS

(71) Applicant: In2Tec Limited, Kettering Northamptonshire (GB)

(72) Inventors: Mark Hudman, Northampton (GB); Neil Armstrong, Coventry (GB); Giuseppe Bonura, Kettering (GB)

(21) Appl. No.: 18/851,820

(22) PCT Filed: Mar. 28, 2023
(86) PCT No.: PCT/GB2023/050803

§ 371 Date: Sep. 27, 2024

(30) Foreign Application Priority Data
Mar. 28, 2022 (GB) 2204378.0

(51) Int. Cl. H05K 13/04; H05K 1/02; H05K 3/32

(52) U.S. Cl. CPC H05K 13/0486; H05K 1/0281; H05K 3/321

(57) ABSTRACT

A method of removing a component part from a substrate of a printed circuit board. The component part is bonded to the substrate by an adhesive and the method comprises exposing the adhesive to a heated solvent to weaken the bond between the component part and the substrate. The method further comprises using an extractor to separate the component part from the substrate and releasably hold the component part.

The invention relates to a method of removing a component from a printed circuit board (PCB) for recycling or reuse. The invention extends to a PCB for use in such a method.

With millions of tonnes of electronic waste (e-waste) being produced every year, it is the world's fastest growing waste stream. A large majority of e-waste is either improperly disposed of or landfilled, which is highly problematic given e-waste contains a high proportion of chemicals that can be harmful to people and the environment, and disposing of e-waste in this manner often leads to contamination of the surrounding soil, water and air. Furthermore, this is not an energy-efficient option given e-waste contains a high proportion of valuable components, and a high proportion of precious metals with a much higher metallic grade than, for example, natural resources, which could be reused in other applications.

PCBs are an example of e-waste which, if correctly recycled or reused in second life applications, could provide significant further value. PCBs may be bare board or may be component populated (PCBAs), and as such they may comprise a large number of electronic components such as resistors, capacitors, inductors, potentiometers, transformers, diodes, transistors, silicon-controlled rectifiers (SCRs), integrated circuits, crystal oscillators, switches, relays, sensors, and the like, and a high proportion of high-grade precious metals such as gold, silver, copper, palladium, tantalum, and the like. This is in addition to the PCB substrate itself which, if manufactured from a suitable material such as PET or PEN, could likewise be recycled or reused.

Conventional methods of recycling PCBs often require large amounts of energy, such as high temperatures (often exceeding 750-1,350° C.), high pressures, and/or the use of mechanical means to crush the PCBs before separating out the metals therein using magnetic or electrostatic methods. As such there is a desire for a process of recycling PCBs which is more energy efficient, and optimises the recyclability or use in second life applications of the components and materials of the PCB.

The invention provides a method of removing a component part from a substrate of a printed circuit board, wherein the component part is bonded to the substrate by an adhesive, the method comprising exposing the adhesive to a heated solvent to weaken the bond between the component part and the substrate; and using an extractor to separate the component part from the substrate and releasably hold the component part.

Weakening yet maintaining the bond between the component part and the substrate until the extractor separates the component part from the substrate enables the component part to be separated from the substrate in a controlled manner. The extractor may be able to locate the component part more easily than if the bond were entirely severed allowing the component part to move freely relative to the substrate. The extractor may be controlled and/or guided automatically and having the component part fixed in a predetermined position relative to the substrate may facilitate automatic control of the extractor. Once the component part is located the extractor is then able to separate the component part from the substrate more easily than had the bond not been weakened. Such a method is particularly helpful when recycling or reusing the component part, as the extractor—with the component part releasably secured thereto—is then able to move the component part to a station and where the component part can be released for further processing, such as cleaning or functional testing, or storage.

The component part may be any component of the PCB which is secured, either directly or indirectly, to the substrate. For example, the component part may be an electronic component such as a resistor, capacitor, inductor, potentiometer, transformer, diode, transistor, silicon-controlled rectifier (SCR), integrated circuit, crystal oscillator, switch, relay, sensor, or the like. The component part may be a non-electronic component, for example, a magnet or structural element such as a rigidiser, i.e. a stiffening component secured to the substrate, either directly or indirectly, to enhance the rigidity of the substrate. The rigidiser may be made of a material such as, but not limited to, metal, aluminium, plastic, nano-cellulose or fibreboard. The rigidiser may be larger, smaller or the same size as the substrate, and/or may be a dissimilar shape to the substrate, or one of multiple rigidisers attached to the substrate, to provide a flexi-rigid combination PCB. There may be a plurality of rigidisers. The substrate may be flexible, and may be made of materials such as polyethylene terephthalate (PET), polyimide, or the like, or composite materials such as FR4, CEM, or the like. In an example, a PCB for use with luminaires has an etched-copper bonded PET substrate which is bonded to an aluminium rigidiser. Such a PCB is beneficial for illuminating LEDS given the aluminium rigidiser can also act as a heatsink. The PCB may have circuitry that is printed with, for example, silver or copper inks, or formed by etching with, for example, copper. The PCB may include component populated (PCBAs) and non-populated electronic substrates. PCBs may have a hard substrate, such as FR4 or CEM, or a flexible such as PET or PEN.

The adhesive may be any adhesive which is suitable for providing a bond between the component part and the substrate to secure the component part to the substrate that is weakenable when exposed to a heated solvent. The adhesive may be any conductive adhesive, such as the ReUSER adhesive C2110716D2. The adhesives may be engineered to utilise thermoplastic, solubility, chemical or other properties of the adhesive material in such a way that the adhesive is sufficiently set at the operating temperature range of the PCB to securely mount the component parts in place, but in a solvent bath at an elevated release temperature, the component parts can be more easily separated. Such thermoplastic materials may have the benefit that they can be reused, and can allow for movement and repositioning of component parts during processing. As an example, the adhesive may be a crosslink thermoset cyclic amine, or the like. The crosslink density of such an adhesive can be controlled by varying the heat to which it is exposed—upon exposure to a heated liquid which is, or which comprises, the heated solvent, the crosslink density may be reduced, thereby weakening the efficacy of the adhesive. The type of adhesive may be dependent on the type of component part the adhesive is securing to the substrate. If the component part is, for example, an electronic component, the adhesive may be a conductive adhesive. The conductive adhesive may be a crosslink thermoset cyclic amine (or the like) with silver particles or ink (or the like) embedded therein. If the component is, for example, a rigidiser, the adhesive may be conductive or non-conductive (such as, for example, a crosslink thermoset cyclic amine, or the like). The adhesives may be screen printed onto the component part and/or the substrate, or printed onto the component part using any other suitable dot dispense printing technique. Where the component part is an electronic component, a conductive adhesive may be printed onto the substrate into a required circuit pattern to both make electronic connections between the components and tracking and secure the components in place.

The heated solvent may be heated water, such as distilled, filtered or tap water. The heated solvent may be ER-SOLV09R. The adhesive may be exposed to the heated solvent by immersing the adhesive in a heated solvent bath. The heated solvent may be heated to a temperature of between 60 and 120° C., for example between 80 to 100° C., preferably 85° C., and may be exposed to the solvent for 30 to 150 seconds for example 50 to 100 seconds, or preferably 65 seconds. The exposure may be for at least 30 seconds, 40 seconds, 50 seconds, 60 seconds, 70 seconds, or at least 80 seconds. The exposure may be for less than 200 seconds, 170 seconds, or less than 150 seconds. It will be appreciated that the exposure time may depend on factors such as the type of components and their dimensions, and the type of adhesive and/or substrate and their dimensions. In particular, immersing a ReUSE® adhesive securing an electronic component to the substrate in a bath of water heated to 80° C. for 60 seconds has been proven to reduce the bond strength of the adhesive by up to 85%, thereby weakening the bond strength yet not severing the bond in its entirety. Immersing the same adhesive securing LEDs to the substrate in a bath of water heated to 85°° C. for 65 seconds has been proven to reduce the bond strength of the adhesive by 90%. The reduction in bond strengths were measured using a digital force gauge. In order to encourage weakening of the bond, the solvent may be agitated using ultrasonic vibration.

Separating the component part from the substrate may comprise one or more of twisting the component part relative to the substrate, sliding the component part relative to the substrate and pulling the component part away from the substrate.

The extractor may engage the component part and break the bond between the component part and the substrate by twisting the component part relative to the substrate. For example, the extractor may first grip, apply suction (for example, using a vacuum) or clip onto the component part to hold it and then twist the component part relative to the substrate to break the bond between the component part and substrate, before moving the component part away from the substrate to separate it therefrom. Twisting the component part relative to the substrate may enable the bond between the component part and the substrate to be broken without having to significantly displace the component part across the substrate, and this may reduce the amount of space required to perform the separation. Twisting the component part relative to the substrate may simplify the movements required by the extractor to separate the component part from the substrate. Twisting the component part relative to the substrate may include twisting the component part by at least 2° about an axis which is perpendicular to the substrate. The axis may pass through the component part, for example through a geometric centre of the component part. In the examples provided above, twisting the component part by 5° has been proven to consistently sever the adhesive bond between the component part and the substrate. Once the bond is broken, the force applied, to the component then only has to be sufficient to maintain grip of the component to move it away from the substrate.

Alternatively, or additionally, the extractor may break the bond between the component part and the substrate by sliding the component part relative to the substrate, for example sliding the component part across a surface of the substrate. This could be achieved by the extractor engaging the component part in any suitable manner, for example as described above. In some examples the extractor may include a mould of the component part to be extracted, and may position the mould around the component part before displacing laterally across the substrate to slide the component relative to the substrate in order to break the bond between the component part and the substrate. The extractor may also grip the component part and/or apply suction to the component part through the mould to ensure control of the component part is maintained.

Alternatively, or additionally, the extractor may break the bond between the component part and the substrate by pulling the component part away from the substrate. For example, the extractor may first grip, apply suction or clip onto the component part to hold it and then pull the component part relative to the substrate to break the bond between the component part and substrate before moving the component part away from the substrate to separate it therefrom. The pulling action may be in any direction away from the substrate; for example, along an axis perpendicular to the substrate. The axis may pass through the component part, for example though a geometric centre of the component part. The extractor may break the bond between the component part and the substrate using any one of the aforementioned methods alone or in combination; for example, the extractor may twist and then pull, or pull and then twist the component.

If the adhesive is being exposed to the heated solvent by immersing it in a heated solvent bath, the extractor may separate the component part from the substrate whilst the PCB is in the hot solvent bath. Alternatively, the PCB may be taken out of the hot solvent bath (for example, via a conveyor belt or robotic arm) and moved to another station, before the extractor separates the component part from the substrate.

The extractor may releasably hold the component part by engaging the component part; for example, by gripping the component part (for example, with pincers), applying suction to the component part, or clipping onto the component part. Alternatively, or additionally, the extractor may releasably hold onto the component part by supporting the component part on a support surface. This may be achieved by, after separating the component part from the substrate, flipping the PCB over such that the component part is transferred to the support surface by gravity. The extractor may releasably hold onto the component part using one or more of these methods; for example, gripping and subsequently, or simultaneously, applying suction to the component part.

The method may further include—once the extractor is releasably holding the component part—moving the component part to a release location. The release location may be a container for holding the component part, or a transport mechanism, for example comprising a conveyor belt, for transferring the component part to a container for holding the component part. The container may be a designated container for holding component parts of the same type; thus, it may contain a plurality of component parts of the same type. The method may further include cleaning the component part with a solvent prior to moving the component part to a release location.

The method may further include cleaning the substrate prior to recycling it. If silver inks have been printed onto the substrate, these can be removed using an appropriate catalyst, prior to recycling the substrate.

The extractor may be attached to, or form part of, a robotic arm and/or gantry, which may be automatically controlled to enact the method steps discussed herein. For example, the robotic arm may be automatically controlled by a computer, a controller, microprocessor or other suitable controller. The extractor may be controlled by the same, or a different controller.

For example, a robotic arm may be provided which carries pincers to provide the extractor and a computer may instruct the robotic arm to extend towards the component and use pincers mounted to the arm to grip the component part, to twist the component part to sever the bond between the component part and the substrate, and—whilst the pincers continue to grip the component part—move the component part away from the substrate to separate the component part from the substrate, The computer may then instruct the robot arm to move the component part to a release location where the pincers can release the component part.

The method may further include identifying the component part prior to separating the component part from the substrate. Identifying the component part may simply mean identifying that a component part attached to the substrate is present. It may include determining the location and orientation of the component part so as to enable it to be separated from the substrate. The component part may be identified as a particular type of component part; for example, an electronic component, or a particular type of electronic component. This may enable the system to selectively locate and separate the component part from the substrate, depending on whether it is desirable to separate the component part from the substrate. It may be that it is desirable to separate only a specific type of component part from the substrate at that station, and that other types of component parts will be separated from the substrate at subsequent stations, or it may be that it is desirable to extract only one particular type of component part from the PCB (for example, because it is a sufficiently high-value component part). The system may have a memory storing various types of components in order to identify the type of component which may be separated from the substrate and how best to extract them. The component part may be identified using a sensor; for example, an image sensor. The component part may be identified after the PCB has been removed from the heated solvent bath; for example, at a first station, or prior to the solvent bath.

As opposed to, or in addition to, identifying the component part directly as suggested above, the type of PCB (of which the component part forms a part) may be identified prior to separating the component part from the substrate and this may allow indirect identification of a component part. For example, a memory of the system may store various types of PCB, and the relative locations of their component parts. Using this memory may allow the type of PCB to be identified, for example using a sensor such as an image sensor and from that identification it may allow one or more of its components to be identified and located based on the stored data.

The PCB or component may be identified by form factor; for example, a ball grid array (BGA) may be identified by pin count and/or size, or a resistor may be identified by shape and/or size. The PCB may also be identified using a sensor; for example, an image sensor. Alternatively, it may be that the system is being used to process only a particular type of PCB; in which case, the system may be informed (for example, by manual input) of which type of PCB is being processed, thereby removing the need for the system to identify the type of PCB.

The component part may be one of a plurality of component parts bonded to the substrate by the adhesive, and the method may comprise exposing the adhesive to a heated solvent to weaken the bond between the plurality of component parts and the substrate; and using the extractor to separate the plurality of component parts from the substrate and releasably hold the plurality of component parts. The adhesive could be conductive in nature and used to couple the component parts to the substrate or a dielectric used to either insulate conductivity between layers or act as a mechanical reinforcement component encapsulant.

The plurality of component parts may be the same type of component part—for example, a plurality of electronic components such as LEDs, or a plurality of a specific type of electronic component—or may be plurality of different types of component part—for example, a rigidiser and one or more electronic components. The plurality of component parts may be separated from the substrate in any of the aforementioned ways. For example, the extractor may grip, apply suction to, clip onto, or otherwise engage the plurality of component parts; twist, slide or pull the plurality of component parts to break the bond between the plurality of component parts and the substrate; and then releasably hold onto the plurality of component parts, for example by gripping the plurality of component parts, applying suction to the plurality of component parts, supporting the plurality of component parts on a support surface, and/or clipping onto the plurality of component parts, before moving the plurality of component parts away from the substrate. The plurality of component parts may be separated from the substrate individually and/or in batches and component parts and/or batches may be separated sequentially or simultaneously.

The extractor may separate the plurality of component parts (for example, a plurality of electronic components) from the substrate and releasably hold the plurality of component parts in a manner such that the relative orientation of the plurality of component parts is substantially maintained. In order to achieve this, the extractor may include a mould of the plurality of component parts, and the extractor may separate the plurality of component parts—whilst maintaining the relative orientation of the plurality of component parts—by fitting the mould around the plurality of component parts and sliding the plurality of component parts relative to the substrate to separate them from the substrate. The component parts may then be sorted (for example, by identifying the types of component part either directly, or by identifying the PCB of which they formed a part).

As previously mentioned, the component part may be an electronic component. Furthermore, the heated solvent may be a first heated solvent, the extractor a first extractor, and the adhesive a conductive adhesive which attaches the electronic component to a first surface of the substrate. The method may further include removing a rigidiser from the substrate, wherein the rigidiser is bonded to a second surface of the substrate by a rigidiser adhesive, wherein the second surface is opposite the first surface (for example, the electronic component is bonded to an upper surface of the substrate and the rigidiser is bonded to a lower surface of the substrate). The rigidiser may be removed by exposing the rigidiser adhesive to a second heated solvent to weaken the bond between the rigidiser and the substrate, and using a second extractor to separate the rigidiser from the substrate and releasably hold the substrate.

In one example, the PCB may be immersed in a first bath containing the first heated solvent in order to weaken the bond between the electronic component and the substrate. The first extractor—which may be attached to a robotic arm—may then separate the electronic component from the substrate and releasably hold the electronic component. The PCB may then be immersed in a second bath containing the second heated solvent in order to weaken the bond between the rigidiser and the substrate, and the second extractor—which may be attached to a robotic arm—may then separate the rigidiser from the substrate and releasably hold the substrate. The electronic component, substrate and rigidiser may then proceed to be processed separately in order to, for example, recycle them. Alternatively, the PCB may be passed through the second bath prior to the first bath for the rigidiser to be removed prior to the electronic component. In these examples, the first extractor and second extractor may be different extractors (for example, attached to a first robotic arm and second robotic arm, respectively), or the first extractor and second extractor may be the same extractor. Furthermore, the first heated solvent and the second heated solvent may be different heated solvents; for example, the solvents may differ and/or they may be heated to a different temperature.

In another example, the PCB may be immersed in a bath containing heated solvent, and the bond between the electronic component and the substrate, and the bond between the rigidiser and the substrate, may be weakened simultaneously. In this example the first solvent is the second solvent. In this example, the first extractor and the second extractor may be the same extractor; in which case the electronic component and the rigidiser may be separated from the substrate sequentially. Alternatively, the first extractor and the second extractor may differ, and the electronic component and rigidiser may be separated from the substrate simultaneously. The rigidiser may be separated from the substrate by slicing the rigidiser therefrom, and may subsequently be air or oven dried for reuse.

In an example, the compound of the rigidiser, rigidiser adhesive and substrate is maintained and recycled, but the electronic component are removed. This compound may then be recycled by repopulating it with new electronic components and/or a new arrangement of electronic components.

The method may further include—once the desired component parts (for example, high-value electronic components) have been separated from the substrate—removing unwanted component parts from the substrate. This may be achieved by slicing the unwanted component parts from the substrate using, for example, a paring blade. These components can then be recycled using traditional mechanisms for material recovery.

The invention also provides a printed circuit board including a substrate and a rigidiser, wherein the rigidiser is bonded to a rigidiser surface of the substrate by a rigidiser adhesive, wherein the bond between the rigidiser and the rigidiser surface is configured to weaken upon exposure to a heated solvent to enable an extractor to separate the rigidiser from the substrate, and wherein one or more of the substrate, rigidiser adhesive and rigidiser have one or more voids or channels through which the solvent can pass to contact regions of the rigidiser adhesive. The voids or channels enable greater access to the rigidiser adhesive for the heated solvent than would be possible if such voids or channels were not present, thereby reducing one or more of the temperature of the solvent, strength of solvent or time of exposure required to sufficiently weaken the bond between the rigidiser and the substrate. Voids may be in only one of the rigidiser or substrate so that a hole through the circuit board is not created. Channels may be provided between the rigidiser and substrate to allow solvent to flow between the rigidiser and substrate. The depth of a channel may be defined by the spacing between the rigidiser and substrate and the width of a channel may be defined, at least in part, on one or both sides, by rigidiser adhesive.

The rigidiser adhesive may be formed of a plurality of strips located on the rigidiser and/or substrate. The strips may be continuous, or discontinuous and may form channels between the strips and/or via discontinuities in the strips. The channels may be in any configuration; for example, they may extend in a criss-cross fashion to enable the heated solvent to access the inner regions of the rigidiser adhesive directly, or via channels and/or voids in the substrate and/or rigidiser.

Alternatively, or additionally, the substrate and/or rigidiser may include one or more channels. The channels may be in any configuration; for example, they may extend in a criss-cross fashion to enable the heated solvent to access inner regions of the rigidiser adhesive. Alternatively, or additionally, the substrate and/or rigidiser may include one or more voids passing through the substrate and/or rigidiser to enable the heated solvent to access the inner regions of the rigidiser adhesive. The voids may extend to one or more of the channels mentioned above, for example those in the rigidiser adhesive to facilitate access to the heated solvent to the rigidiser adhesive.

The PCB described above may not include any electronic components, and may therefore may be a bare board. Alternatively, the PCB may comprise at least one electronic component. The printed circuit board including a substrate and a rigidiser may also include a plurality of electronic components (it may be a component-populated PCBA), wherein the plurality of electronic components are bonded to an electronic component surface of the substrate by a conductive adhesive, wherein the electronic component surface is opposite the rigidiser surface (for example, the electronic component surface is an upper surface of the substrate and the rigidiser surface is a lower surface of the substrate), and wherein the bond between the plurality of electronic components and the electronic component surface is configured to weaken upon exposure to the heated solvent to enable the extractor to separate the electronic components from the substrate. The bond between the plurality of electronic components and the substrate typically takes less time to weaken than the bond between the rigidiser and the substrate given it is often thinner or more sparse; therefore, the voids or channels can prove particularly beneficial when removing both electronic components and a rigidiser from a PCB, as they may reduce the time required to sufficiently weaken the bond between the rigidiser and substrate to match the time required to weaken the bond between the electronic components and substrate, thereby simplifying the disassembly of the PCB.

These and other aspects of the invention will now be described by way of example only with reference to the following drawings, in which

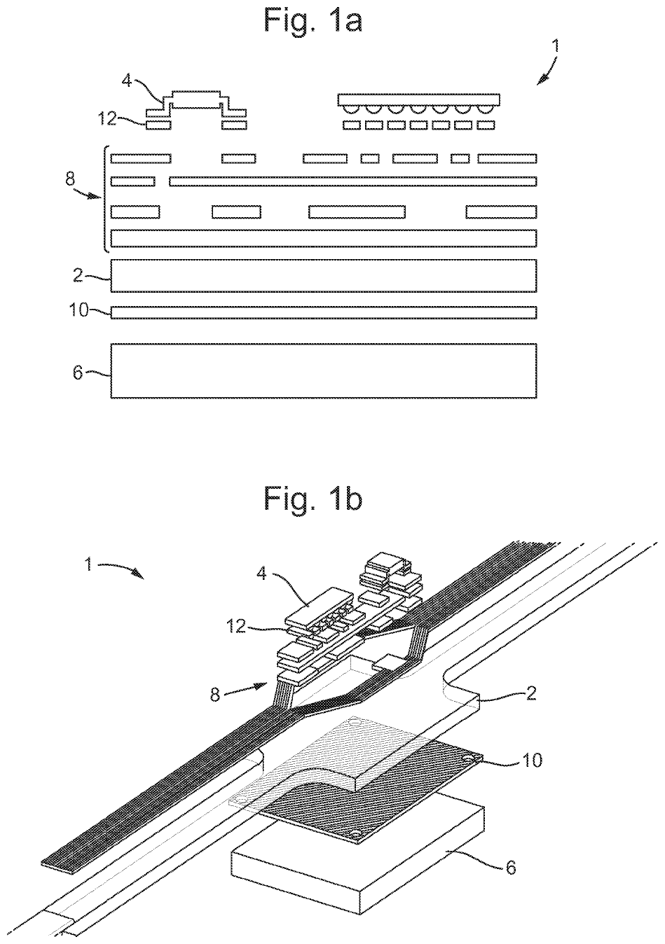

FIG. 1a shows a schematic cross-section of an exploded PCB;

FIG. 1b shows an exploded perspective view of the PCB of FIG. 1a;

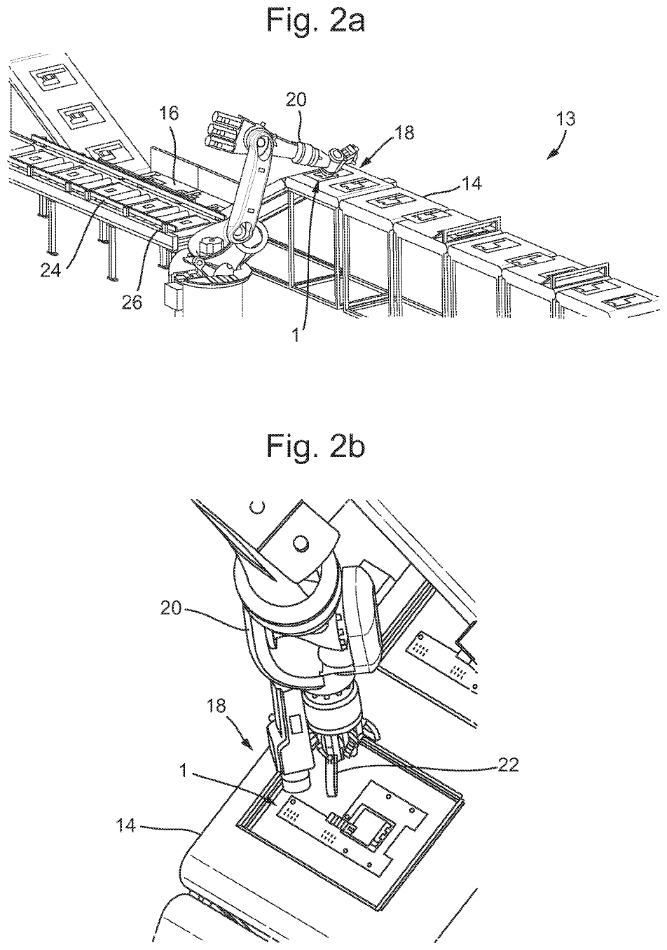

FIG. 2a shows a disassembly line for the PCB of FIG. 1a;

FIG. 2b shows the PCB on the disassembly line of FIG. 2a;

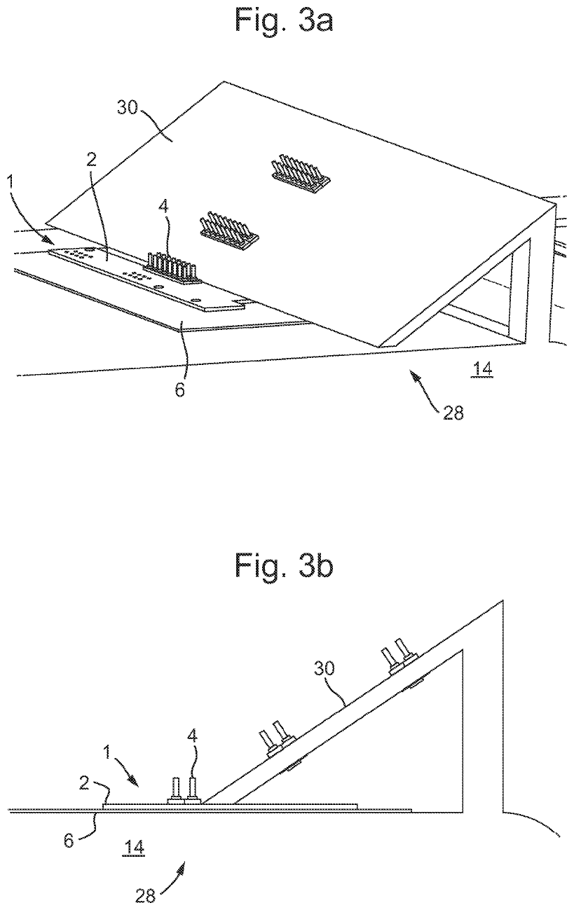

FIG. 3a shows a first view of unwanted electronic components being separated from a substrate of a PCB;

FIG. 3b shows a second view of the unwanted electronic components being separated from the substrate of the PCB as shown in FIG. 3a;

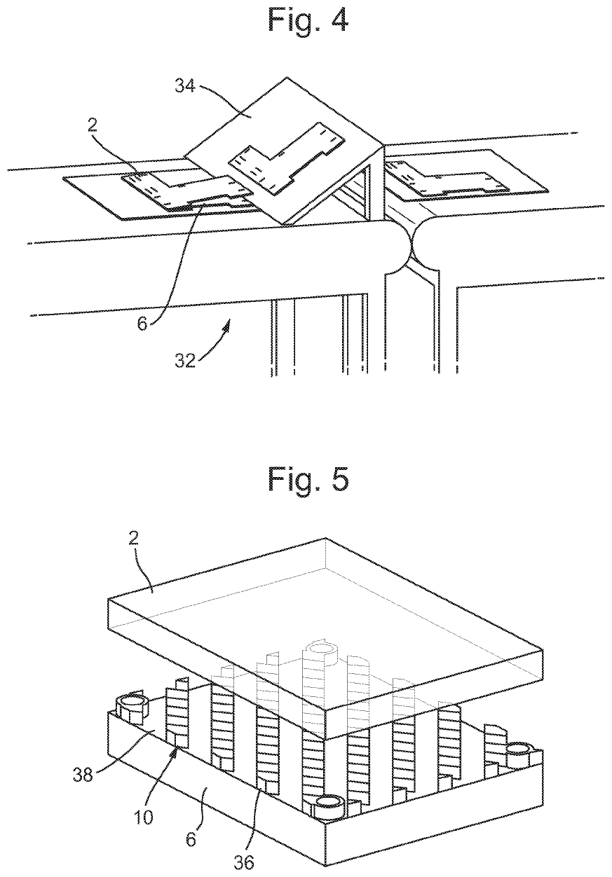

FIG. 4 shows a rigidiser being removed from a substrate of a PCB;

FIG. 5 shows a rigidiser adhesive including channels; and

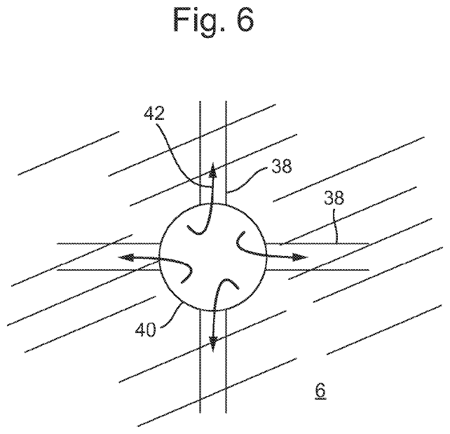

FIG. 6 shows an aerial view of a schematic representation of a void in a substrate.

FIGS. 1a and 1b show a schematic exploded cross-section and exploded perspective view, respectively, of a PCB 1. The PCB 1 includes a substrate 2 with a tracking 8 attached thereto on a first surface (which may be an upward-facing surface) of the substrate 2. The tracking may provide for electrical connection with external components (for example, power supplies, external circuits etc.). Multiple tracking layers can be separated by layers of dielectric. The PCB 1 also includes electronic components 4 which are attached to the first surface of the PCB 1 via an electronic component adhesive 12, in this case a conductive adhesive. Furthermore, the PCB1 comprises a rigidiser 6 which is attached to a second surface (which may be a downward-facing surface) of the PCB 1 via a rigidiser adhesive 10, which may, or may not, be conductive.

FIGS. 2a and 2b show a disassembly line for PCB 1. PCB 1 is carried by a first conveyor 14 into a bath 16 containing a heated solvent, in order to weaken the bond between the electronic components 4 and the substrate 2 and/or the bond between the rigidiser 6 and the substrate 2. In this example the heated solvent is water heated to 85° C. The PCB 1 is then carried out of the bath 16 by the first conveyor 14 to a first station 18. In this example the PCB 1 remains in the bath 16 for between 50 and 100 seconds. At first station 18, a robotic arm 20 with a first extractor 22, in this case a set of pincers, attached thereto is operated to separate one or more component parts 4,6 from the substrate 2. The component parts may include one or more of the electronic components 4 and/or the rigidiser 6. The extractor 22 releasably holds the one or more component parts 4,6 and moves to a second conveyor 24 and where the one or more component parts 4,6 are released at a second station 26 of the second conveyor 24, to be carried away for further processing.

FIGS. 3a and 3b show a third station 28 with a first inclined surface 30 installed thereon to act as a paring blade for removing unwanted electronic components 4 from the substrate 2. The first inclined surface 30 is a conveying inclined surface. The PCB 1 reaches the third station 28 after the first station 18, and the third station 28 may be part of the first conveyor 14 or the second conveyor 24. As the PCB 1 meets the first inclined surface 30, the bond between the unwanted electronic components 4 and the substrate 2 is severed (for example, by slicing) and the first inclined surface 30 carries the unwanted electronic components 4 away thereby separating them from the substrate 2. A robotic arm (for example the robotic arm 20) may then pick up the unwanted electronic components 4 to move them elsewhere (for example, to the second station 26); for example, for further processing or collection.

FIG. 4 shows a fourth station 32 with a second inclined surface 34 installed thereon to act as a paring blade for removing the substrate 2 from the rigidiser 6. The second inclined surface 34 is a conveying inclined surface. The PCB 1 reaches the fourth station 32 after the third station 28. As the PCB 1 meets the second inclined surface 34, the bond between the substrate 2 and the rigidiser 6 is severed (for example, by slicing) and the second inclined surface 34 carries the substrate 2 away thereby separating it from the rigidiser 6. A robotic arm (for example, the robotic arm 20) may then pick up the substrate 2 and/or rigidiser 6 to move it elsewhere; for example, for further processing or collection.

FIG. 5 shows an example of the rigidiser adhesive 10 which functions to secure the rigidiser 6 to the substrate 2. The rigidiser adhesive 10 is formed in a series of strips 36 which defines a plurality of channels 38. The rigidiser adhesive 10 is on a first surface (which may be an upward-facing surface) of the rigidiser 6 which is intended to contact the second surface of a substrate 2. The channels 38 are shown as extending in a criss-cross pattern.

FIG. 6 shows an aerial view of a schematic representation of a void 40 through a substrate 2. In this example the void 40 is a circular hole through the substrate 2 which provides the heated solvent with access to the rigidiser adhesive 10. It should be understood that the void may take any suitable shape, regular or irregular. Arrows 42 show the direction of flow of the heated solvent through the void 40 into channels 38 which, in this example, are present within the rigidiser adhesive 10 below.

1. A method of removing a component part from a substrate of a printed circuit board, wherein the component part is bonded to the substrate by an adhesive, the method comprising
exposing the adhesive to a heated solvent to weaken the bond between the component part and the substrate; and
using an extractor to separate the component part from the substrate and releasably hold the component part.

2. The method as claimed in claim 1, wherein separating the component part from the substrate comprises one or more of:
twisting the component part relative to the substrate;
sliding the component part relative to the substrate; and
pulling the component part away from the substrate.

3. The method as claimed in claim 2, wherein twisting the component part relative to the substrate comprises twisting the component by at least 2 degrees about an axis perpendicular to the substrate that passes through the component part.

4. The method as claimed in claim 1, wherein the extractor releasably holds the component part by one or more of gripping the component part;
applying suction to the component part;
supporting the component part on a support surface; and
clipping onto the component part.

5. The method as claimed in claim 1, wherein the solvent is water.

6. The method as claimed in claim 5, wherein the water is heated to 80-100° C. for a period of 100 seconds.

7. (canceled)

8. The method as claimed in claim 1, wherein the solvent is agitated using ultrasonic vibration.

9. The method as claimed in claim 1, further comprising moving the component part to a release location.

10. The method as claimed in claim 1, wherein the extractor is attached to a robotic arm.

11. The method as claimed in claim 1, further comprising one of
identifying the component part prior to separating the component part from the substrate; and
identifying the type of printed circuit board prior to separating the component part from the substrate to locate the component.

12-13. (canceled)

14. The method as claimed in claim 1, wherein the component part is one of a plurality of component parts bonded to the substrate by the adhesive, the method comprising
exposing the adhesive to a heated solvent to weaken the bond between the plurality of component parts and the substrate; and
using the extractor to separate the plurality of component parts from the substrate and releasably hold the plurality of component parts, such that the relative orientation of the plurality of component parts is substantially maintained.

15. The method as claimed in claim 14, wherein the plurality of component parts are separated from the substrate simultaneously.

16. The method as claimed in claim 15, wherein the extractor comprises a mould of the plurality of component parts.

17. The method as claimed in claim 1, wherein the component part is an electronic component, the heated solvent is a first heated solvent, the extractor is a first extractor, and the adhesive is a conductive adhesive which attaches the electronic component to a first surface of the substrate.

18. The method as claimed in claim 17, the method further comprising removing a rigidiser from the substrate of the printed circuit board, wherein the rigidiser is bonded to a second surface of the substrate by a rigidiser adhesive, wherein the second surface is opposite the first surface, by
exposing the rigidiser adhesive to a second heated solvent to weaken the bond between the rigidiser and the substrate; and
using a second extractor to separate the rigidiser from the substrate and releasably hold the rigidiser.

19. The method as claimed in claim 18, wherein one or more of the rigidiser, the non-conductive adhesive and the substrate comprise voids and/or channels through which the second solvent can pass to contact regions of the non-conductive adhesive.

20-21. (canceled)

22. The method as claimed in claim 18, wherein the rigidiser is separated from the substrate by slicing.

23. The method as claimed in claim 18, the method further comprising drying the rigidiser by air or oven.

24. A printed circuit board comprising
a substrate; and
a rigidiser, wherein the rigidiser is bonded to a rigidiser surface of the substrate by a rigidiser adhesive,
wherein the bond between the rigidiser and the rigidiser surface is configured to weaken upon exposure to a heated solvent to enable an extractor to separate the rigidiser from the substrate, and
wherein one or more of the substrate, rigidiser adhesive and rigidiser have one or more voids or channels through which the solvent can pass to contact regions of the rigidiser adhesive.

25. The printed circuit board as claimed in claim 24, the printed circuit board further comprising
a plurality of electronic components, wherein the plurality of electronic components are bonded to an electronic component surface of the substrate by a conductive adhesive,
wherein the electronic component surface is opposite the rigidiser surface, and
wherein the bond between the plurality of electronic components and the electronic component surface is configured to weaken upon exposure to the heated solvent to enable the extractor to separate the electronic components from the substrate.
